(19) United States
(12) Patent Application Publication
(10) Pub. No.: US 2010/0180937 A1
(43) Pub. Date: Jul. 22, 2010

(54) HOLOGRAPHIC ENERGY-COLLECTING MEDIUM AND ASSOCIATED DEVICE

(75) Inventors: Sumeet Jain, Niskayuna, NY (US); Moitreyee Sinha, Niskayuna, NY (US); Brian Lee Lawrence, Waunakee, WI (US); Michael Teruki Takemori, Rexford, NY (US); Mark Allen Cheverton, Mechanicville, NY (US); Andrew Arthur Burns, Schenectady, NY (US); Amitabh Bansal, Hoboken, NJ (US)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: GENERAL ELECTRIC COMPANY, SCHENECTADY, NY (US)

(21) Appl. No.: 12/750,759

(22) Filed: Mar. 31, 2010

Related U.S. Application Data
(63) Continuation-in-part of application No. 12/164,147, filed on Jun. 30, 2008.

(51) Int. Cl. H01L 31/00; G03F 7/20; G02B 5/32

(52) U.S. Cl. 136/255; 430/2; 359/15; 136/256

(57) ABSTRACT

An energy-collecting medium including an optically transparent holographic layer is presented. The energy-collecting medium includes a photochemically active dye and an optically transparent polymer material. Also provided is a method for making an optically transparent holographic layer. An energy conversion device including the energy-collecting medium is also provided.

### CROSS REFERENCE TO RELATED APPLICATIONS

This application is a continuation in part of U.S. patent application Ser. No. 12/164,147, entitled “HOLOGRAPHIC RECORDING MEDIUM,” filed on Jun. 30, 2008, which is herein incorporated by reference.

### BACKGROUND

The invention relates generally to the field of an energy concentrator. In particular, the invention relates to a holographic layer used to divert, collect and concentrate incident light in one or more specified directions.

Solar energy is abundant in many parts of the world throughout the year. Solar cells typically include multiple layers formed on a substrate, and thus solar cell manufacturing typically requires a significant number of processing steps. As a result of their complex manufacturing and low working efficiencies, the cost of generating electricity with these cells, has historically been very high.

Among the main drawbacks of these solar cells are low efficiencies in converting solar energy into electricity and variation in the incident solar energy depending on the locale, time of the day and the month of the year. For example, typical solar cells achieve conversion efficiencies of less than about 20 percent, thus large areas must be covered with solar panels to generate sufficient electricity and will only function optimally for a short portion of the day that the sun is directly pointed at them.

One way to increase the amount of energy collected by a particular solar cell is through solar concentration that is collecting light over a large area and directing it to a small photovoltaic cell area. Solar concentrators can be used to collect and focus solar energy to achieve higher conversion efficiency in solar cells. A few examples of solar concentrators are parabolic mirrors, mirror arrays, luminescent (up-conversion/down-conversion phosphors), electromagnetic wave concentrators and holographic layers. Holographic layers can be used as solar concentrators by changing the direction of light incident on a surface towards a photovoltaic device embedded in or attached to the surface.

A particular advantage of holographic layers for solar concentration is the potential to collect a portion of incident light without completely blocking the incident light and thus allowing holographic solar energy modules to be used in applications such as window glazing which are not currently possible for opaque solar modules. In case of holographic solar energy modules, the aesthetics and functionality of a window (or façade) can be combined with solar energy generation to collect light, which would otherwise be a waste. Thus, use of holographic layers dramatically increase the potential area over which solar energy collecting devices could be arrayed on building surfaces and helps to realize the potential of building integrated photovoltaics (BIPV).

The concentration efficiency of a holographic light concentration device may depend on the material used for holographic layers. Recent developments have led to the development of dye-doped polymeric materials into which holograms can be written using two interfering laser beams. These materials offer facile processing into films and parts compatible with the solar concentration application, unlike other holographic materials such as photopolymers and silver halide materials, which are difficult to handle and require significant post-processing in order to reveal an embedded hologram. The sensitivity of a dye-doped material may depend on the concentration of the dye, the dye's absorption cross-section at the recording wavelength, the quantum efficiency of the photochemical transition, and the index change of the dye molecule for a unit dye density. However, as the product of dye concentration and the absorption cross-section increases, the collecting medium (for example, a holographic film) may become opaque, which may complicate both recording and readout.

Accordingly, there remains a need for an improved solution to the long-standing problem of inefficient and complicated solar energy concentrator devices and methods of manufacture

### BRIEF DESCRIPTION OF THE INVENTION

In one embodiment, an energy-collecting medium including an optically transparent holographic layer is provided. The energy-collecting medium includes a photochemically active dye and an optically transparent polymer material.

Another embodiment provides an energy conversion device including an energy-collecting medium. The energy-collecting medium includes an optically transparent holographic layer and at least one photovoltaic device disposed over at least a portion of a surface of the energy-collecting medium. The optically transparent holographic layer includes a photochemically active dye and an optically transparent polymer material.

In one embodiment, a method for making an optically transparent holographic layer is provided. The method includes providing an optically transparent layer that includes a photochemically active dye and an optically transparent polymer material. The method further includes creating a holographic pattern and thereby partly converting the photochemically active dye into a photo-product.

### DRAWINGS

These and other features, aspects, and advantages of the present invention will become better understood when the following detailed description is read with reference to the accompanying drawings, wherein:

FIG. 1 is a schematic of an energy-collecting medium in accordance with one embodiment of the invention.

FIG. 2 is a schematic of an energy-collecting medium in accordance with another embodiment of the invention.

FIG. 3A is a schematic of an energy-collecting medium in accordance with yet another embodiment of the invention.

FIG. 3B is a schematic of an energy-collecting medium in accordance with yet another embodiment of the invention.

FIG. 4 is a schematic of an energy conversion device in accordance with one embodiment of the invention.

FIG. 5 is a schematic of an energy-collecting medium in accordance with one embodiment of the invention.

### DETAILED DESCRIPTION

The invention includes embodiments that may relate to a holographic layer used to divert, collect and concentrate incident light in a particular direction.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims that follow, the singular forms “a,” “an,” and “the” include plural referents unless the context clearly dictates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances, an event or capacity can be expected, while in other circumstances the event or capacity cannot occur—this distinction is captured by the terms “may” and “may be”.

Embodiments of the invention provide an energy-collecting medium. The energy-collecting medium includes an optically transparent holographic layer. As used herein, the term “optically transparent” means that a layer or a material is capable of transmitting a substantial portion of solar radiation. The substantial portion may be at least about 70% of the solar radiation. The optical transparency of the layer may depend on the material and the thickness of the layer. The optically transparent holographic layer may also be referred to as a holographic layer.

As used herein, the term “holographic layer” refers to a layer containing a holographic pattern having a plurality of diffractive structures or holograms. As used herein, the term “holographic pattern” refers to a pattern of holograms created in a specific geometry. A hologram is defined as a three-dimensional interference pattern that can interact with a beam of incident light of a particular wavelength or range of wavelengths to redirect the light in a particular direction. Other wavelengths of light and light rays from other directions are not redirected and pass through the hologram. The holographic pattern may be created by the intersection of two or more coherent and interfering beams of light (also referred to as a signal beam and a reference beam) in a photosensitive medium.

The diffractive structures or holograms are created/patterned/recorded to collect and divert or redirect incident light. The diffractive structures or holograms may be recorded as reflection or transmission holograms that bend incident light or radiation in a specific direction. In one embodiment, the holographic layer may include a plurality of transmission holograms, a plurality of reflection holograms or a combination of transmission holograms and reflection holograms. Moreover, holograms may be created/recorded throughout the thickness of a holographic layer or only through a portion of the thickness of the holographic layer.

Transmission holograms are recorded with the signal beam and the reference beam incident on the same side of a sample and reflection holograms are recorded with the two beams on opposite sides of the sample. Transmission holograms direct light such that the diffracted component propagates toward an opposite surface of the sample relative to a surface of incidence, while reflection holograms direct diffracted light towards the surface through which the light entered.

In several embodiments of this invention, upon interaction with the holograms, the incident light beam is diffracted such that a portion of the incident light is totally internally reflected and guided within the energy-collecting medium. Total internal reflection refers to the propagation of light rays within a material such that a ray incident on the internal surface of the material at a particular angle is reflected back into the material, rather than escaping into the environment. The angle, at which total internal reflection occurs, known as the critical angle, depends upon the refractive indices of the material and the environment surrounding the material. Once the diffracted light has begun total internal reflection, the diffracted light remains guided within the energy-collecting medium until the diffracted light encounters a surface at an angle beyond the critical angle and is transmitted out of the material.

In one embodiment, the incident light is diffracted such that a portion of incident light is redirected to a particular direction. In another embodiment, the incident light is diffracted such that a portion of the incident light is transmitted through the holographic layer to increase the amount of light that is transmitted through the structure.

Diffractive structures or holograms are directionally selective and may be designed and generated depending on a particular application. For example, each hologram may divert light incident at different angles to collect light over a wide range of angles or a number of holograms may be generated to divert light rays incident at the same angle to enhance collection from a certain direction. Directional selectivity means that only light rays from a range of desired and selected incident angles are collected and redirected. In one embodiment, holograms are configured to collect light incident at an angle ranging from about 0 degrees to about 90 degrees with respect to the surface normal of the holographic layer. In another embodiment, the holograms are configured to collect light incident at an angle ranging from about 0 degrees to about 30 degrees with respect to the surface normal of the holographic layer. In one embodiment, each hologram in the holographic layer is configured to divert light rays incident at the same angle. In another embodiment, each hologram is configured to divert light rays incident at different angles. The holograms may be further configured to divert and guide a range of wavelengths of an incident light in a specific direction within the holographic layer.

In one embodiment, holograms can be recorded in the holographic layer at a given diffraction efficiency. The diffraction efficiency of a hologram in the holographic layer is defined as the percentage of an incident beam of light diffracted by a particular hologram, relative to the incident beam intensity. According to an embodiment of the invention, the hologram in the holographic layer is capable of having diffraction efficiency of greater than about 20 percent.

In one embodiment, a plurality of the optically transparent holographic layers may be layered or stacked, with each layer configured to collect and guide light beams incident at different angles and in different ranges of wavelengths. The energy-collecting medium having the plurality of holographic layers makes it possible to collect a wide range of incident angles and wavelengths. Moreover, the plurality of optically transparent holographic layers may have any combination of two or more holographic layers having a plurality of reflection holograms, a plurality of transmission holograms or a combination of reflection and transmission holograms.

The thickness of the holographic layer may depend on various parameters, such as the material comprising the layer, the desired number of holograms in that layer, the diffraction efficiency of the holograms and/or the number of holographic layers in the energy-collecting medium. In one embodiment, each holographic layer has a thickness in a range of from about 5 microns to about 50000 microns, and in a specific embodiment, from about 50 microns to about 5000 microns.

In one embodiment, the optically transparent holographic layer includes a photochemically active dye and an optically transparent polymer material. The photochemically active dye may be described as a dye molecule that has an optical absorption spectrum characterized by a center wavelength associated with the maximum (peak) absorption and a spectral width (full width at half of the maximum, FWHM) of less than about 500 nanometers. In addition, the photochemically active dye molecule may undergo a partial light induced chemical reaction when exposed to light with a wavelength within the absorption range to form at least one photo-product. A photo-product may be defined as the result of light interaction with the photochemically active dye during the recording of a holographic pattern. In one embodiment, the photoproduct may include a new chemical form of the photochemically active dye after light interaction. In various embodiments, this reaction may be a photo-decomposition reaction, such as oxidation, reduction, or bond-breaking to form smaller constituents, or a molecular rearrangement, such as a sigmatropic rearrangement, or addition reactions including pericyclic cycloadditions.

In various embodiments, the photochemically active dye (hereinafter sometimes referred to as “dye”) may be selected and utilized on the basis of several characteristics, including the ability to change the refractive index of the dye upon exposure to light; the efficiency with which the light creates the refractive index change; and the separation between the wavelength at which the dye shows a maximum absorption and the desired wavelength or wavelengths to be used for collecting, concentrating and bending the light. The choice of the photochemically active dye depends upon many factors, such as concentration of the photochemically active dye, the dye's absorption cross section (σ) at the recording wavelength, the quantum efficiency (QE) of the photochemical conversion of the dye, and the refractive index change per unit dye density. In one embodiment, photochemically active dyes that show a high refractive index change per unit dye density, a high quantum efficiency in the photochemical conversion step, and a low absorption cross-section at the wavelength of light (electromagnetic radiation) used for the photochemical conversion are selected.

In one embodiment, the photochemically active dye may be a vicinal diarylethene. In one embodiment, the photochemically active dye may be a nitrone. In one embodiment, the photochemically active dye may be a nitrostilbene. In one embodiment, the photochemically active dye may be a phenantherequinone. Any combination having two or more members selected from the group consisting of a vicinal diarylethene, a photo-product derived from a vicinal diarylethene, a nitrone, a nitrostilbene and a phenanthrenequinone may also be used.

Vicinal diarylethenes can be reacted in the presence of actinic radiation (i.e. radiation that can produce a photochemical reaction), such as light. In an embodiment, a photo-product derived from a vicinal diarylethene can be used as a photochemically active dye. An example of vicinal diarylethene is 1,2-bis{2-(4-methoxyphenyl)-5-methylthien-4-yl}-3,3,4,4,5,5-hexafluorocyclopent-1-ene. This vicinal diarylethene shows a UV absorbance of about 1 at about 600 nanometers, the wavelength at which it cyclizes intramolecularly, and a high QE of about 0.8 for the cyclization step. Other examples of suitable vicinal diarylethenes that can be used as photochemically active dyes include diarylperfluorocyclopentenes, diarylmaleic anhydrides, diarylmaleimides, or a combination including at least one of the foregoing diarylethenes. The vicinal diarylethenes can be prepared using methods known in the art.

Nitrones may be used as photochemically active dyes for producing the holographic layer for the energy-collecting medium. An exemplary nitrone may include an aryl nitrone. The nitrone may be alpha-aryl-N-arylnitrones or conjugated analogs thereof in which the conjugation is between the aryl group and an alpha-carbon atom. The alpha-aryl group is frequently substituted, often by a dialkylamino group, in which the alkyl groups contain 1 to about 4 carbon atoms. Suitable, non-limiting examples of nitrones include alpha-(4-diethylaminophenyl)-N-phenylnitrone; alpha-(4-diethylaminophenyl)-N-(4-chlorophenyl)-nitrone, alpha-(4-diethylamino phenyl)-N-(3,4-dichlorophenyl)-nitrone, alpha-(4-diethylaminophenyl)-N-(4-carbethoxyphenyl)-nitrone, alpha-(4-diethylaminophenyl)-N-(4-acetylphenyl)-nitrone, alpha-(4-dimethylaminophenyl)-N-(4-cyanophenyl)-nitrone, alpha-(4-methoxyphenyl)-N-(4-cyanophenyl)nitrone, alpha-(9-julolidinyl)-N-phenylnitrone, alpha-(9-julolidinyl)-N-(4-chlorophenyl)nitrone, alpha-(4-dimethylamino)styryl-N-phenylnitrone, alpha-styryl-N-phenyl nitrone, alpha-[2-(1,1-diphenylethenyl)]-N-phenylnitrone, alpha-[2-(1-phenylpropenyl)]-N-phenylnitrone, 2,5-thiophene-bis-2-ethylhexylesterphenyl dinitrone; or a combination including at least one of the foregoing nitrones. In one embodiment, the photochemically active dye is alpha-(4-dimethylamino)styryl-N-phenylnitrone. In one embodiment, the photochemically active dye is 2,5-thiophene-bis-2-ethylhexylesterphenyl dinitrone.

In one embodiment, the photochemically active dye is a nitrostilbene compound. Nitrostilbene compounds are illustrated by 4-dimethylamino-2′,4′-dinitrostilbene, 4-dimethylamino-4′-cyano-2′-nitrostilbene, 4-hydroxy-2′,4′-dinitrostilbene, and the like. The nitrostilbene can be a cis isomer, a trans isomer, or mixtures of the cis and trans isomers. Thus, in one embodiment, the photochemically active dye useful for producing a holographic layer includes at least one member selected from the group consisting of 4-dimethylamino-2′,4′-dinitrostilbene, 4-dimethylamino-4′-cyano-2′-nitrostilbene, 4-hydroxy-2′,4′-dinitrostilbene, 4-methoxy-2′,4′-dinitrostilbene, alpha-(4-diethylaminophenyl)-N-phenylnitrone; alpha-(4-diethylaminophenyl)-N-(4-chlorophenyl)-nitrone, alpha-(4-diethylaminophenyl)-N-(3,4-dichlorophenyl)-nitrone, alpha-(4-diethylaminophenyl)-N-(4-carbethoxyphenyl)-nitrone, alpha-(4-diethylaminophenyl)-N-(4-acetylphenyl)-nitrone, alpha-(4-dimethylaminophenyl)-N-(4-cyanophenyl)-nitrone, alpha-(4-methoxyphenyl)-N-(4-cyanophenyl)nitrone, alpha-(9-julolidinyl)-N-phenylnitrone, alpha-(9-julolidinyl)-N-(4-chlorophenyl)nitrone, alpha-[2-(1,1-diphenylethenyl)]-N-phenylnitrone, and alpha-[2-(1-phenylpropenyl)]-N-phenylnitrone.

In one embodiment, the photochemically active dye is a photoreactive aromatic cyclodione that is a member of one or more of the classes of quinine, benzoquinone, phenanthrenequinone, anthracenedione or chrysenedione. Photoreactive cyclodione dyes generate a refractive index change through photoaddition of the aromatic cyclodione to molecules of the polymer material comprising the matrix, specifically in the regions illuminated by the constructive interference of the writing laser beams. The material is then heat treated to evenly distribute the remaining un-reacted aromatic cyclodione molecules by diffusion, which are themselves anchored to the polymer material through a final uniform light exposure. This process generates regions of locally high dye density (the recorded holographic diffraction grating) on a background of uniformly low dye density, thus generating the index of refraction change necessary to generate the hologram. Because of the post-writing diffusion and fixing steps, aromatic cyclodione-based holographic materials exhibit minimal photodegradation compared to other dye-based systems. To tailor the aromatic cyclodione system to optimize recording wavelength, quantum yield, coloration, diffusion kinetics, etc., a wide variety of aromatic cyclodione systems were synthesized and tested for hologram writing. In one embodiment, the photochemically active dye useful for producing a holographic layer includes at least one member selected from the group consisting of 9,10-phenanthrenequinone, dinitro-9,10-phenanthrenequinone, 2-nitro-9,10-phenanthrenequinone, 1-isopropyl-7-methyl-9,10-phenanthrenequinone, amino-9,10-phenanthrenequinone, 4,5-dinitro-9,10-phenanthrenequinone, 3-chloro-6-methoxy-9,10-phenanthrenequinone, 2,6-dimethoxy-9,10-phenanthrenequinone, 3-methoxy-9,10-phenanthrenequinone, 3-fluoro-6-methoxy-9,10-phenanthrenequinone, 3,4-difluoro-6-methoxy-9,10-phenanthrenequinone, 3-methoxy-6-methyl-9,10-phenanthrenequinone, dihydroxy-9,10-phenanthrenequinone, methyl-9,10-phenanthrenequinone, hydroxy-9,10-phenanthrenequinone, 11,12-dihydrochrysene-11,12-dione, 5,6-chrysenedione, Benz[a]anthracene-5,6-dione, anthracene-9,10-dione, aminoanthracene-9,10-dione, 9,10-dioxo-9,10-dihydroanthracene-2-carboxylic acid, 2-amino-3-hydroxyanthracene-9,10-dione, naphthalene-1,4-dione, benzoquinone, or quinine.

In one embodiment, the photochemically active dye may be admixed with other additives to form a photo-active material. Examples of such additives include heat stabilizers; antioxidants; light stabilizers; plasticizers; antistatic agents; mold releasing agents; additional resins; binders, blowing agents; and the like, as well as combinations of the foregoing additives. In one embodiment, the photo-active materials may be used for manufacturing the holographic layer.

The holographic layer further includes an optically transparent polymer material having sufficient optical quality, for example, low scatter, low birefringence, and negligible losses at the wavelengths of interest, to collect the solar radiation in the energy-collecting medium. Polymeric materials, such as, oligomers, dendrimers, ionomers, copolymers (such as block copolymers, random copolymers, graft copolymers, star block copolymers; or the like) or a combination including at least one of the foregoing polymers can be used. Thermoplastic polymers or thermosetting polymers can be used. Examples of suitable thermoplastic polymers include polyacrylates, polymethacrylates, polyamides, polyesters, polyolefins, polycarbonates, polystyrenes, polyesters, polyamideimides, polyarylates, polyarylsulfones, polyethersulfones, polyphenylene sulfides, polysulfones, polyimides, polyetherimides, polyetherketones, polyether etherketones, polyether ketone, polysiloxanes, polyurethanes, polyarylene ethers, polyethers, polyether amides, polyether esters, or the like, or a combination including at least one of the foregoing thermoplastic polymers. Some more possible examples of suitable thermoplastic polymers include, but are not limited to, amorphous and semi-crystalline thermoplastic polymers and polymer blends, such as: polyvinyl chloride, linear and cyclic polyolefins, chlorinated polyethylene, polypropylene, and the like; hydrogenated polysulfones, ABS resins, hydrogenated polystyrenes, syndiotactic and atactic polystyrenes, polycyclohexyl ethylene, styrene-acrylonitrile copolymer, styrene-maleic anhydride copolymer, and the like; polybutadiene, polymethylmethacrylate (PMMA), methyl methacrylate-polyimide copolymers; polyacrylonitrile, polyacetals, polyphenylene ethers, including, but not limited to, those derived from 2,6-dimethylphenol and copolymers with 2,3,6-trimethylphenol, and the like; ethylene-vinyl acetate copolymers, polyvinyl acetate, ethylene-tetrafluoroethylene copolymer, aromatic polyesters, polyvinyl fluoride, polyvinylidene fluoride, and polyvinylidene chloride.

In some embodiments, the thermoplastic polymer disclosed herein as a polymer material is made of a polycarbonate. The polycarbonate may be an aromatic polycarbonate, an aliphatic polycarbonate, or a polycarbonate including both aromatic and aliphatic structural units.

Examples of useful thermosetting polymers include those selected from the group consisting of an epoxy, a phenolic, a polysiloxane, a polyester, a polyurethane, a polyamide, a polyacrylate, a polymethacrylate, and a combination including at least one of the foregoing thermosetting polymers.

The photochemically active dye and the optically transparent polymer material may be mixed together by any known method. In one embodiment, the photochemically active dye is dispersed in the optically transparent polymer material. In another embodiment, the photochemically active dye is blended with the polymer material. In yet another embodiment, the photochemically active dye is chemically attached to the polymer material. The term “chemically attached” means that the photochemically active dye chemically reacts with the polymer material and a reaction product is used for manufacturing the holographic layer.

In one embodiment, the amount of photochemically active dye present in the holographic layer is in a range of about 0.1 weight percent to about 20 weight percent. In one embodiment, the amount of photochemically active dye present is in a range of about 2.5 weight percent to about 6 weight percent, and in a specific embodiment, of about 3 weight percent to about 5 weight percent.

Some embodiments of the invention provide a method of manufacturing an optically transparent holographic layer. The method includes providing an optically transparent layer including a photochemically active dye and an optically transparent polymer material. Various film-formation methods may be used for forming the optically transparent layer, such as injection molding, solvent casting or extrusion. The film formation may include spin casting. The optically transparent layer has a peak absorbance of greater than 1 at a wavelength in a range of from about 200 nanometers to about 1000 nanometers. The optically transparent layer is capable of having a diffraction efficiency of greater than about 20 percent.

The method further includes creating simultaneously a holographic pattern and thereby partly converting the photochemically active dye into a photo-product (as defined above). The holographic pattern is created or formed by irradiating the optically transparent layer with two or more coherent, interfering light beams at a wavelength in the range from about 200 nm to 1000 nm.

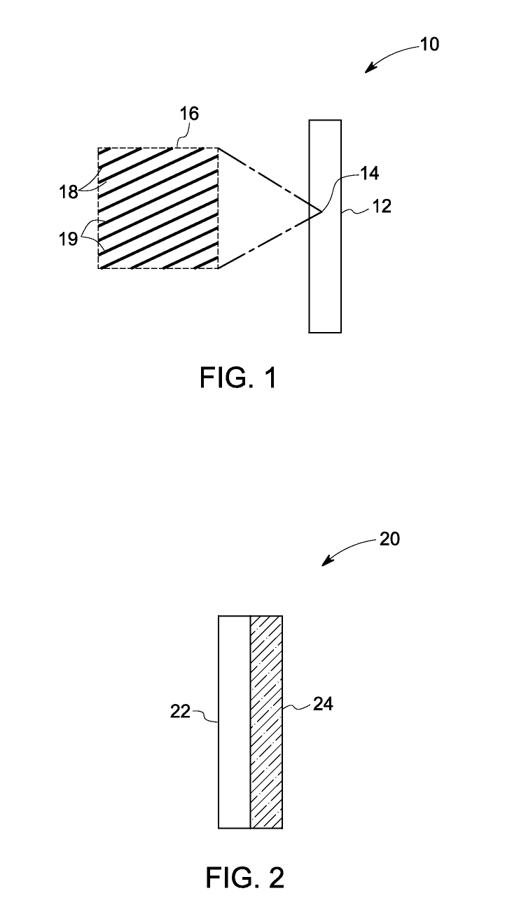

FIG. 1 illustrates an energy-collecting medium 10, according to various embodiments of the invention. The energy-collecting medium 10 includes an optically transparent holographic layer 12. In these embodiments, the holographic layer is a free-standing layer and may be used as the energy-collecting medium 10 without any support. The exploded view shows a hologram 14 containing interference patterns 16 of high refractive index fringes 18 and low refractive index fringes 19.

FIG. 2 schematically illustrates another embodiment of an energy-collecting medium 20. The energy-collecting medium 20 includes a holographic layer 22 disposed on an optically transparent substrate 24. The substrate 24 provides support to the holographic layer 22. The holographic layer 22 may be placed on the front or rear surface of the substrate, in turn meaning that the holographic layer 22 or the substrate 24 may be directly exposed to incident light.

The optically transparent substrate, as used herein, refers to a substrate capable of transmitting a substantial portion of solar radiation. The substantial portion may be at least about 70% of the solar radiation. In one embodiment, the optically transparent substrate is made of glass. Other suitable examples for the substrate may include a thermoplastic polymer, a thermosetting polymer or a combination of thermoplastic and thermosetting polymers.

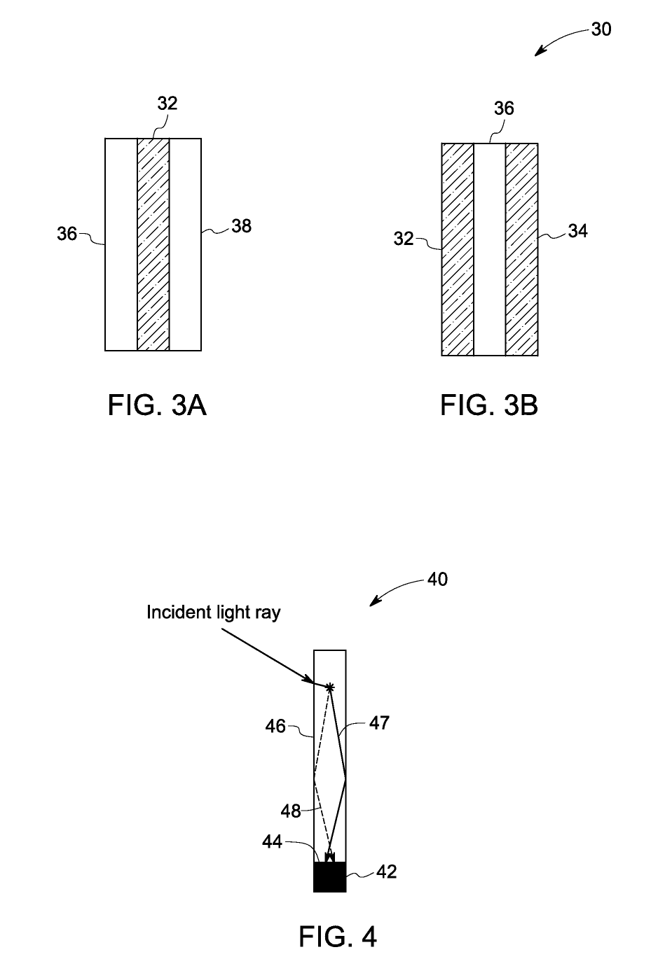

In some embodiments, one or more optically transparent holographic layers or one or more optically transparent substrates may be used in different configurations to form an energy-collecting medium. FIG. 3A illustrates an embodiment of an energy-collecting medium 30 including two holographic layers 36 and 38 disposed on opposite surfaces of an optically transparent substrate 32. FIG. 3B illustrates another embodiment of an energy-collecting medium 30 having a holographic layer 36 sandwiched between two optically transparent substrates, 32 and 34. Referring to FIG. 3B, the two optically transparent substrates, 32 and 34 provide mechanical strength and relatively high protection to the holographic layer.

Different configurations of the energy-collecting medium may be possible based on the use of reflection or transmission holograms, in multiple holographic layers as discussed in the above embodiments. Depending on the intended use of the energy-collecting medium, it may be advantageous to have different configurations to divert and concentrate light rays of desired and selected wavelengths and incident angles in particular directions.

For example, if such an energy-collecting medium was integrated into a window, skylight or façade of a building, it could be used to concentrate a portion of the incident light for solar power generation, while allowing the remainder of the light to pass through the window, skylight or façade for ambient lighting and aesthetics. In such a case, light rays of specified wavelength and direction incident on a hologram within the energy-collecting medium would be diffracted such that a portion of the incident light would propagate within the energy-collecting medium by total internal reflection in the direction of an attached photovoltaic cell as shown in FIG. 4 (described below). The remainder of the light that does not interact with the hologram, is not diffracted or redirected and passes through the holographic layer into the space to allow ambient lighting of the space within, as well as maintaining visibility and aesthetics. This would allow a portion of the incident light to be harnessed for photovoltaic power generation, offsetting the power requirements of the building, and provides an alternative to the current reflective finishes used on commercial window glazing that simply reflect a certain percentage of the ambient light.

According to one embodiment of the invention, a photovoltaic device is disposed to cover at least a portion of a surface of the energy-collecting medium to enhance the performance of the photovoltaic device. In certain embodiments, the photovoltaic device is disposed along the edge of the energy-collecting medium. The energy-collecting medium collects and guides solar energy or light within/through the material towards the photovoltaic device where it is converted to electrical energy. A photovoltaic cell or a thin film photovoltaic cell may be used as the photovoltaic device.

Such an embodiment is illustrated in FIG. 4. An energy conversion device 40 includes a photovoltaic device 42 disposed on an edge 44 of an energy-collecting medium 46. The energy-collecting medium 46 diverts and redirects a wavelength or a range of wavelengths of incident solar radiation towards the photovoltaic device 42 to produce electrical energy. Solid line 47 and dotted line 48, respectively, show propagation paths of light rays within the energy-collecting medium 46 after light rays interaction with a transmission hologram or a reflection hologram.

A variety of photovoltaic devices may be disposed or attached to the energy-collecting medium. In one embodiment, the photovoltaic device is a single junction or a multi-junction photovoltaic cell. Non-limiting examples of photovoltaic devices include an amorphous silicon cell, a crystalline silicon cell, a hybrid/heterojunction amorphous and crystalline silicon cell, a CdTe thin film cell, a micromorph tandem silicon thin film cell, a Cu(In,Ga)Se₂ (CIGS) thin film cell, a GaAs cell, a multiple-junction III-V-based solar cell, a dye-sensitized solar cell, or a solid-state organic/polymer solar cell.

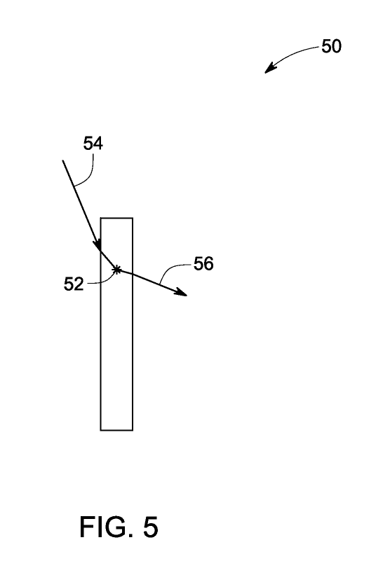

A further application of the energy-collecting medium in a window, skylight or façade would be in directionally selective diffraction for ambient light modulation. For example, due to low solar intensity and low angles at which solar rays incident on windows, skylights and facades, indoor lighting needs are greatest at the beginning and end of the day. In one embodiment, an energy-collecting medium 50 as illustrated in FIG. 5, may be applied to the enhancement of ambient light intensity early and late in the day. For such an application, hologram 52 may be designed to collect low-angle solar rays 54 and divert the rays such that the rays 56 transmit through the glazing to light the building interior, rather than being reflected internally or externally. Such redirection of light to the building interior would require less ambient lighting during daylight hours, lowering the power requirements of the structure. Further, such ambient light modulation could be incorporated along with holographic structures for solar power generation tuned to capture light incident during the peak brightness of the day, when ambient lighting needs are least.

The energy-collecting medium may be used to collect either direct light from the sun or diffused light, such as light through clouds or light reflected from the surrounding environment. According to the embodiments of the invention, the energy-collecting medium is capable of collecting and diverting light rays in the range of about 300 nm to about 1400 nm, and particularly in the range of about 350 nm to about 1000 nm.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An energy-collecting medium comprising an optically transparent holographic layer, wherein the energy-collecting medium comprises a photochemically active dye and an optically transparent polymer material.

2. The energy-collecting medium of claim 1, wherein the optically transparent holographic layer comprises a plurality of diffractive structures (holograms).

3. The energy-collecting medium of claim 2, wherein the plurality of diffractive structure comprises transmission holograms, reflection holograms or a combination thereof.

4. The energy-collecting medium of claim 2, wherein the diffractive structures are configured to guide a range of wavelengths of an incident light in a specific direction.

5. The energy-collecting medium of claim 2, wherein the diffractive structures are configured to collect light incident at an angle ranging from about 0 degrees to about 90 degrees vertically with respect to a normal to the optically transparent holographic layer.

6. The energy-collecting medium of claim 2, wherein the diffractive structures are configured to collect light incident at an angle ranging from about 0 degrees to about 30 degrees vertically with respect to a normal of the optically transparent holographic layer.

7. The energy-collecting medium of claim 1, wherein the optically transparent holographic layer comprises a plurality of layers.

8. The energy-collecting medium of claim 8, wherein each of the plurality of layers has a thickness in a range from about 5 to about 50000 microns.

9. The energy-collecting medium of claim 8, wherein each of the plurality of layers has a thickness in a range from about 50 to about 5000 microns

10. The energy-collecting medium of claim 1, wherein each of the plurality of layers has a thickness and each of the plurality of layers comprises diffractive structures through a portion of the thickness of each layer

11. The energy-collecting medium of claim 1, wherein a photochemically active dye comprises a vicinal diarylethene.

12. The energy-collecting medium of claim 1, wherein a photochemically active dye comprises a nitrone.

13. The energy-collecting medium of claim 1, wherein the photochemically active dye comprises a nitrostilbene.

14. The energy-collecting medium of claim 1, wherein the photochemically active dye comprises a photoreactive aromatic cyclodione.

15. The energy-collecting medium of claim 14, wherein the photoreactive aromatic cyclodione comprises a cyclic aromatic hydrocarbon selected from one or more of quinine, benzoquinone, phenanthrenedione, anthracenedione and chrysenedione.

16. The energy-collecting medium of claim 1, wherein the optically transparent holographic layer further comprises a photo-product of the photochemically active dye.

17. The energy-collecting medium of claim 16, wherein the photo-product generates a local change in index of refraction.

18. The energy-collecting medium of claim 1, wherein the optically transparent polymer material comprises a thermoplastic polymer, a thermosetting polymer, or a combination of a thermoplastic polymer and a thermosetting polymer.

19. The energy-collecting medium of claim 1, further comprises an optically transparent substrate.

20. The energy-collecting medium of claim 19, wherein the optically transparent substrate comprises a glass.

21. The energy-collecting medium of claim 19, wherein the optically transparent substrate comprises a thermoplastic polymer, a thermosetting polymer, or a combination of a thermoplastic polymer and a thermosetting polymer.

22. An energy conversion device, comprising:
an energy-collecting medium comprising an optically transparent holographic layer and at least one photovoltaic device disposed to cover at least a portion of a surface of the energy-collecting medium, wherein the optically transparent holographic layer comprises a photochemically active dye, and an optically transparent polymer material.

23. The energy conversion device of claim 22, wherein the photovoltaic device is disposed on a surface of the energy collecting medium.

24. The energy conversion device of claim 22, wherein a photovoltaic device is disposed along one or more edges of the energy-collecting medium.

25. The energy conversion device of claim 22, wherein the photovoltaic device comprises a single junction or a multi-junction photovoltaic cell.

26. A method for making an an optically transparent holographic layer comprising:
providing an optically transparent layer comprises a photochemically active dye and an optically transparent polymer material, and
creating a holographic pattern and thereby partly converting the photochemically active dye into a photo-product.

27. The method of claim 26, wherein creating a holographic pattern comprises irradiating the optically transparent layer with two or more coherent, interfering light beams at a wavelength in the range from about 200 nm to 1000 nm.
